(19) United States
(12) Patent Application Publication
(10) Pub. No.: US 2010/0169481 A1
(43) Pub. Date: Jul. 1, 2010

(54) TEST SYSTEM FOR SEMICONDUCTOR DEVICES BASED ON NETWORK MONITORING

(76) Inventor: Tsan-Fu Hung, Changhua County (TW)

Correspondence Address: Muncy, Geissler, Olds & Lowe, PLLC, 4000 Legato Road, Suite 310, FAIRFAX, VA, 22033, US

(21) Appl. No.: 12/629,557

(22) Filed: Dec. 2, 2009

(30) Foreign Application Priority Data
Dec. 31, 2008 (TW) 097223944

(51) Int. Cl. G06F 15/173; G01R 31/26

(52) U.S. Cl. 709/224; 324/765

(57) ABSTRACT

A test system for semiconductor devices based on network monitoring is disclosed. The test system includes a testing apparatus, a test system server and one or more control terminals. The test system server wirelessly receives the test request transmitted from the testing apparatus, the control terminals, the designing apparatus or the manufacturing apparatus. According to the test request, the test system sever wirelessly transmits the test information to the testing apparatus to proceed with a test process for a semiconductor device.

### CROSS REFERENCE TO RELATED APPLICATIONS

This Application claims priority of Taiwan Patent Application No. 097223944, filed on Dec. 31, 2008, the entirety of which is incorporated by reference herein.

### BACKGROUND OF THE INVENTION

1. Field of the Invention

The invention relates to a test system, and more particularly to a test system for semiconductor devices based on network monitoring.

2. Description of the Related Art

With respect to current semiconductor technology, a test process must be implemented on dies of a semiconductor wafer before the wafer is shipped to customers or installed on products. For a back-end process, dies in wafer form are singularized, packaged, burned in, and tested. In another semiconductor process, the dies on the wafer are cut without being packaged, tested, and burned in to generate “known good dies”. In an advanced semiconductor process, a wafer level test process is provided so that the dies in wafer form are burned in and completely tested.

For the back-end process, an advanced test system for semiconductor devices capable of higher efficiency is required.

### BRIEF SUMMARY OF THE INVENTION

Test systems for semiconductor devices based on network monitoring are provided. An exemplary embodiment of a test system for semiconductor devices based on network monitoring comprises a testing apparatus, a test system server, and one or more control terminals. The testing apparatus tests a semiconductor device for a test process. The test system server wirelessly transmits test information to the testing apparatus for the test process and wirelessly receives a test result from the testing apparatus. The control terminals wirelessly receive the test information from the test system server to wirelessly transmit the test information to the testing apparatus for the test process. The test system server wirelessly receives a test request transmitted from a designing apparatus, a manufacturing apparatus, or the control terminals and wirelessly transmits the test result to the designing apparatus, the manufacturing apparatus or the control terminals.

Another embodiment of a test system for semiconductor devices based on network monitoring comprises a testing apparatus and a test system server. The testing apparatus tests a semiconductor device for a test process. The test system server wirelessly transmits test information to the testing apparatus for the test process and wirelessly receives a test result from the testing apparatus. The test system server wirelessly receives a test request transmitted from a designing apparatus, a manufacturing apparatus, or the testing apparatus and wirelessly transmits the test result to the designing apparatus or the manufacturing apparatus.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic view of a test system for semiconductor devices of the present invention;

FIG. 2 is a schematic view of a testing station of the present invention;

FIG. 3 is a schematic view of a first controller of the present invention;

FIG. 4 is a schematic view of a second controller of the present invention;

FIG. 5 is a schematic view of a tester of the present invention;

FIG. 6 is a schematic view of another embodiment of a test system for semiconductor devices of the present invention; and

FIG. 7 is a schematic view of a test system server of the present invention.

### DETAILED DESCRIPTION OF THE INVENTION

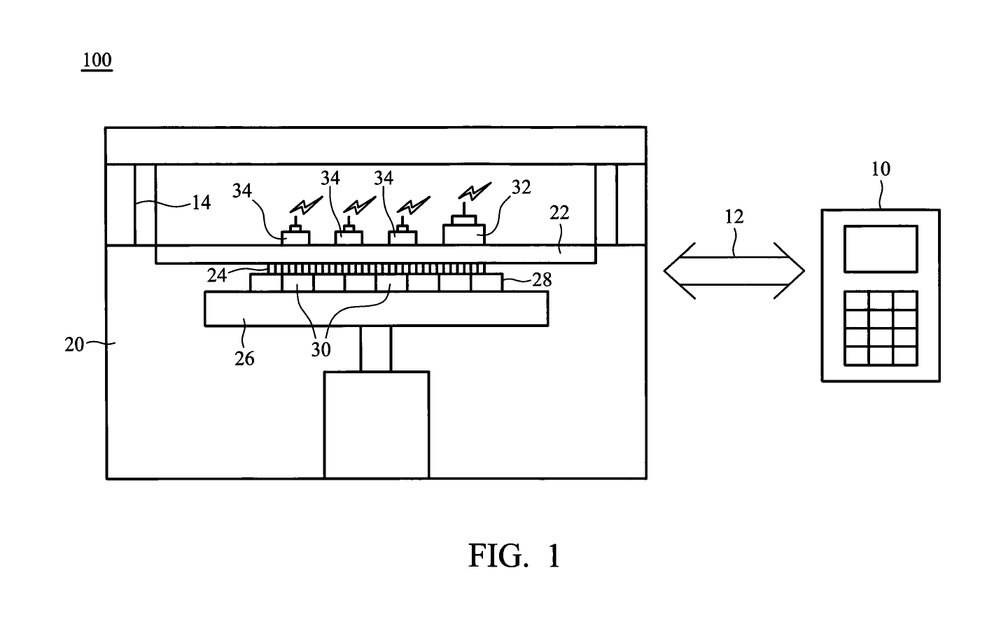

Several exemplary embodiments of the invention are described with reference to FIGS. 1 through 7, which generally relate to a test system for semiconductor devices based on network monitoring. It is to be understood that the following disclosure provides various different embodiments as examples for implementing different features of the invention. Specific examples of components and arrangements are described in the following to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various described embodiments and/or configurations.

The invention discloses a test system for semiconductor devices based on network monitoring.

FIG. 1 is a schematic view of a test system for semiconductor devices of the present invention.

The test system for semiconductor devices comprises a tester 10 and a testing station 20. The tester 10 can be applied for testing any suitable semiconductor devices, such as semiconductor dies of an uncut semiconductor wafer or cut dies (packaged or unpackaged). The cut dies can also be packaged as modules to be tested. In an exemplary embodiment, the tester 10 is a portable device and communicates with the testing station 20 via a transmission path 12 for transmitting information. The transmission comprises an infrared transmission path, which can also be implemented by physical or wireless transmission. The information generally comprises data signals, address signals, control signals, state signals, test signals generated by the tester, and response signals generated by the dies under test. The test process comprises electrical characteristic testing or wafer probe testing.

Operations of the test system 100 are next described. The tester 10 generates test data and transmits the test data to the testing station 20 via the transmission path 12 to perform the test process. Probes 24 of a probe card 22 contact with a wafer 28 residing on a platform 26. The platform 26 can support and move a wafer 28. The wafer 28 comprises a plurality of dies under test 30. The platform 20 provides the test data for the dies 30 of the wafer 25 via the probes 24 of the probe card 22 and receives response signals from the dies 30. The dies 30 can be any types of semiconductor chips, comprising, but is not limited to, memory chips, microprocessors or microcontrollers, signal processors, analog chips, application specific integrated circuits (ASIC), digital logic circuits, and so forth.

A first controller 32 comprises an infrared transmission module, coupled to the tester 10 via a connector 14 and the transmission path 12. The test data which is provided by the tester 10 and used for testing the dies 30 of the wafer 28 is provided for the first controller 32 via the transmission path 12. When the dies 30 have been tested, response data thereof is transmitted to the tester 10 via the first controller 32.

The probe card 22 comprises plural second controllers 34 and an infrared communication module as well. Thus, the first controller 32 can broadcast test data received from the tester 10 to the second controllers 34 via infrared transmission. The test data is then electronically transmitted to the dies 30 via a conductive circuit (not shown) via of the probe card 22 using the second controllers 34. Response data generated by the dies 30 is transmitted to the tester 10 via the second controllers 34, the first controller 32, and the transmission 12.

The second controllers 34 can respectively control test processes of the dies 30, wherein each of the second controllers 34 corresponds to one or a multiple of the dies 30. The first controller 32 creates a flexible and extendable transmission interface between the first controller 32 and the tester 10 using the second controllers 34. For example, the number of the transmission channels between the tester 10 and the test station 20 is fixed so that the tester 10 can only test a predetermined number of dies at one time. By changing the number of the transmission interfaces between the first controller 32 and the second controllers 34 and the number of the second controllers 34, the number of the dies 30 to be tested can be increased without changing the number of transmission channels connecting to the tester 10.

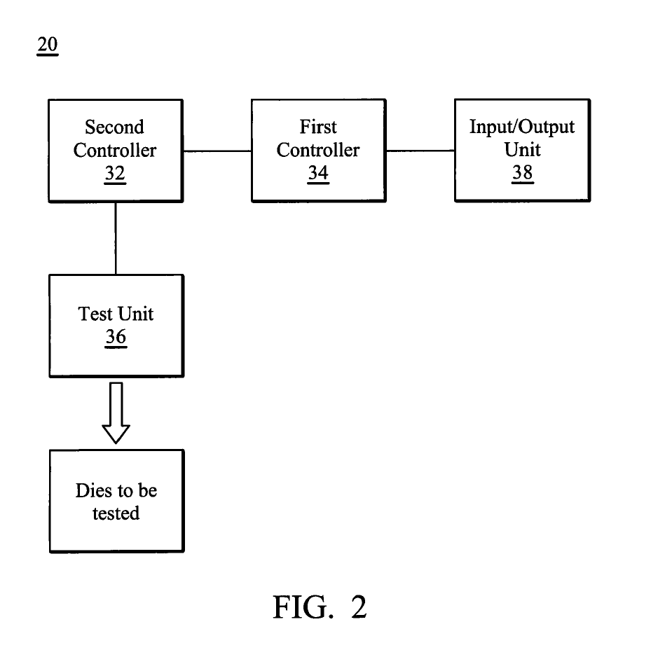

FIG. 2 is a schematic view of the test station 20 of the present invention.

The test station 20 comprises a first controller 32, a plurality of second controllers 34, a test unit 36, and an input/output unit 38. The first controller 32 handles operations of the test station 20. Further, the first controller 21 transmits information to the second controllers 34 via infrared transmission for handling operations of the second controllers 34. The second controllers 34 correspond to one or a multiple of dies to be tested and transmit test instructions or information to the test unit 36 for performing a test process. The test unit 36 receives the test instructions, implements a test process to the dies to be tested, and transmits a test result to the second controllers 34. The second controllers 34 transmit the test result to the first controller 32 via infrared transmission. The first controller 32 transmits the test result to an external tester via the input/output unit 38. In an exemplary embodiment, the test unit 36 comprises a probe card.

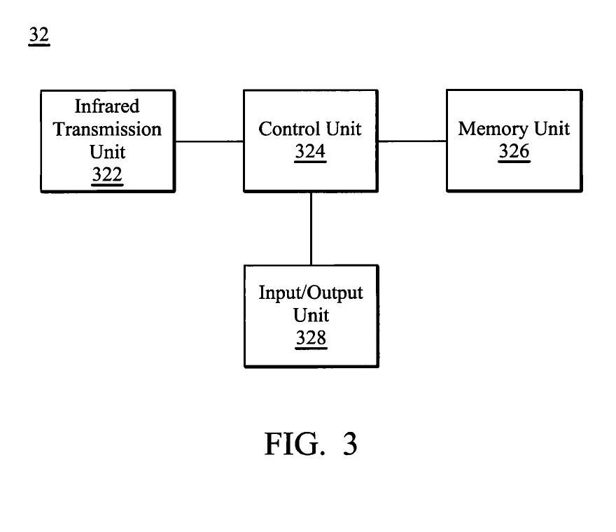

FIG. 3 is a schematic view of a first controller 32 of the present invention.

Multiple functions of the first controller 32 can be integrated as an integrated circuit or a multiple of integrated circuits. The first controller 32 comprises an infrared transmission unit 322, a control unit 324, a memory unit 326, and an input/output unit 328. The infrared transmission unit 322 can transmit test signals to the second controllers 34 via wireless transmission or receive the test results from the second controllers 34 via the wireless transmission. The control unit 324 handles operations of the first controller 32. The control unit 324 can be integrated in a microprocessor operating under software control, a logic circuit providing a fixed number of circuits, or combinations thereof. The memory unit 326 stores data or software performed by the control unit 324. The input/output unit 328 provides a physical input/output interface between the first controller 32 and the test station 20.

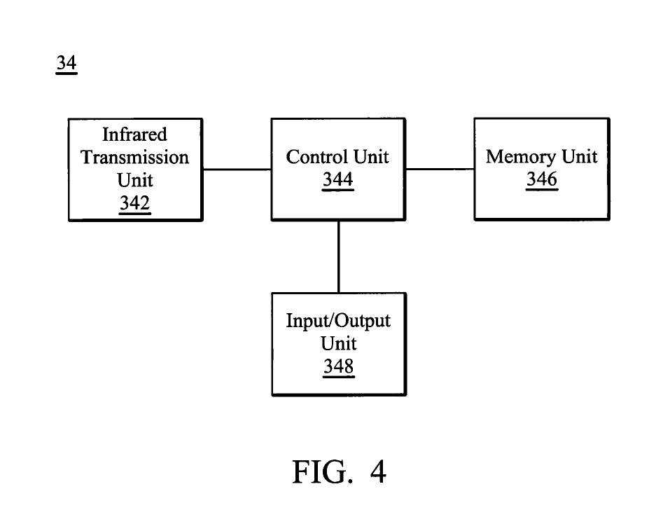

FIG. 4 is a schematic view of the second controllers 34 of the present invention.

In an exemplary embodiment, the second controllers 34 can be a control module capable of infrared transmission, multiple functions of which can be integrated as an integrated circuit or a multiple of integrated circuits. The first controllers 34 comprise an infrared transmission unit 342, a control unit 344, a memory unit 346, and a probe input/output unit 348. The infrared transmission unit 342 can transmit the test result to the first controller 32 via wireless transmission or receive the test signals from the first controller 32 via the wireless transmission. The control unit 344 handles operations of the second controllers 34. The control unit 344 can be integrated in a microprocessor operating under software control, a logic circuit providing a fixed number of circuits, or combinations thereof. The memory unit 346 stores data or software performed by the control unit 344. The input/output unit 348 provides a physical input/output interface between the second controllers 34 and the probe 24.

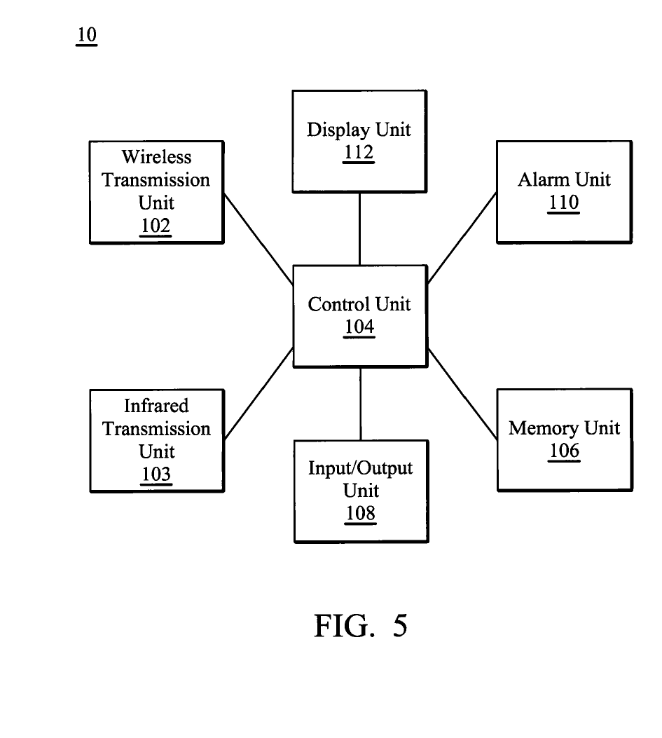

FIG. 5 is a schematic view of the tester 10 of the present invention.

The tester 10 comprises a wireless transmission unit 102, an infrared transmission unit 103, a control unit 104, a memory unit 106, an input unit 108, an alarm unit 110, and a display unit 112. The wireless transmission unit 102 transmits wireless signals between the tester 10 and an external station (not shown). The infrared transmission unit 103 transmits infrared signals between the tester 10 and the test station 20. The control unit 104 handles operations of the tester 10. The control unit 104 can be integrated in a microprocessor operating under software control, a logic circuit providing a fixed number of circuits, or combinations thereof. The memory unit 106 stores data or software performed by the control unit 106. The input unit 108 acts as an input interface of the tester 10. In an exemplary embodiment, the input unit may be a keyboard, a touch screen or a voice control device for inputting instructions. The alarm unit 110 sends a notification message at a preset state for reminding the user of the tester 10. In an exemplary embodiment, the alarm unit 110 may be a speaker, a buzzer or a micromotor for generating text, audio or vibrating signals to notify the user. The display unit 112 provides a display function. In an exemplary embodiment, the tester 10 can display an operational interface with a graphical user interface (GUI) on the display unit 112, providing human interest operations. In an exemplary embodiment, the tester 10 comprises a portable device, such as a mobile terminal.

Operations of the test system for semiconductor devices 100 are described in the following. Test schedules can be preset or test schedule information stored in the memory unit 106 of the tester 10 can be accessed or downloaded using the wireless transmission unit 102. When a predetermined date and time is reached, the alarm unit 110 sends a notification message to the user.

Next, the tester 10 recognizes the test station 20 to be tested via the infrared transmission unit 102 based on the test schedule information. Each test station 20 comprises an identification code. The tester 10 recognizes the test station 20 corresponding to a test process and creates a transmission interface to perform the test process. The tester 10 recognizes that the test station 20 can be operated if operational authority of the user and information carried by the test schedule are allowed and then controls the test station 20.

When a test station 20 is allowed, the tester 10 initiates the state of the test station 20 that enables the state of the first controller 32 of the test station 20 corresponding to the states of the second controllers 34 and creates a transmission protocol, such as frequency division multiple access (FDMA) or time division multiple access (TDMA), for setting transmission between the first controller 32 and the second controllers 34. If the test station 20 comprises multiple first controllers 32, each of the first controllers 32 can assign corresponding second controllers at different frequencies or times.

When the test station 20 is set, the tester 10 transmits test information or instruction to the test station 20 via the transmission path 12 for performing a test process. The first controller 32 receives and broadcasts the test information or instruction to corresponding second controllers 34. When the test information or instruction is received, the second controllers 34 transmit the test information to the dies 30 to be tested via the probe 24 of the probe card 22 to perform the test process.

The dies 30 which have been tested generate a test result based on the test process and the test result is transmitted to corresponding second controllers 34 via the probe 24 and the conductive path (not shown) of the probe card 22. The second controllers 24 receive test results from the dies 30 and transmit the test result to the first controller 32 via infrared transmission. The first controller 32 transmits the test results to the tester 10 via the transmission path 12 and displays test result on the display unit 112 of the tester 10.

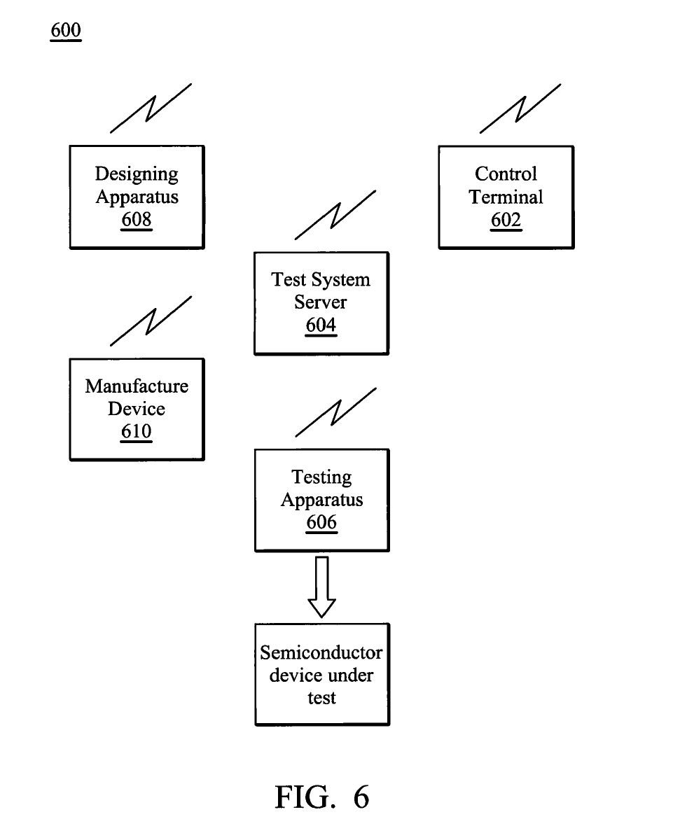

FIG. 6 is a schematic view of another embodiment of a test system for semiconductor devices of the present invention.

A portion of the components of the test system 600 is similar to the components shown in FIG. 1, thus, similar portions are not further described. The test system 600 comprises a control terminal 602, a test system server 604, and a testing apparatus 606. A designing apparatus 608 designs a constitution of a semiconductor device and a manufacture device 610 manufactures the semiconductor device according to the design. The manufactured semiconductor device should be provided for the testing apparatus 606 to be tested.

The control terminal 602, the testing apparatus 606, the designing apparatus 608, or the manufacture device 610 can wirelessly transmit a test request to the test system server 604 and the test system server 604 arranges a test process and transmits the test data to the testing apparatus 606 to proceed with the test process.

The control terminal 602 is similar to the tester 10 shown in FIG. 5, which is used for controlling operations of the testing apparatus 606. The control terminal 602 can preset test schedules or accesses test schedule information stored in a memory thereof or wirelessly download or upload test schedule information stored in the test system server 604. The control terminal 602 wirelessly transmits the test information to the testing apparatus 606 based on the test schedules or the test data for the test process. In an exemplary embodiment, the control terminal 602 can also transmit the test request to the test system server 604 to ask the testing apparatus 606 to proceed with the test process. The test system server 604 verifies the authority of the control terminal 602 transmitting the test request. If the authority is qualified, the test system server 604 wirelessly transmits the test data or a command to the testing apparatus 606. The testing apparatus 606 receiving the test data implements the test process on the semiconductor device. The test data or command may be of any type of data applicable for testing semiconductor devices or dies. The test data can be used by the testing apparatus 606 to perform a specific test. The test data can be test vectors written in the dies or combinations thereof of test commands and vectors.

The test system server 604 controls operations of the testing apparatus 606, receives test requests transmitted from the control terminal 602, the testing device 606, the designing apparatus 608, and the manufacturing apparatus 608, and controls the testing apparatus 606 according to the test requests. The test system server 604 can wirelessly transmit the test data to the testing apparatus 606 for controlling or initializing the test process of the testing apparatus 606.

The testing apparatus 606 tests semiconductor devices generated by the manufacturing apparatus. In an exemplary embodiment, the test process of the testing apparatus 606 comprises electrical characteristic testing or wafer probe testing. The testing apparatus 606 can also comprise cutting or packaging apparatuses.

When the test process has been completed, the testing apparatus 606 wirelessly transmits the test result to the test system server 604. The test system server 604 wirelessly transmits the test result to the control terminal 602, the designing apparatus 608, and/or the manufacturing apparatus 610 based on received requests. The test result can be any type of data. For example, the test result can be raw input data generated after the semiconductor device has been tested. The test result can be abstract or an analysis of the raw input data. The testing apparatus 606, the designing apparatus 608 or the manufacturing apparatus 610 modifies the design or process of the semiconductor device according to the test result for improving the quality or yield rate of the semiconductor device.

The process performed by the designing apparatus 608 and the manufacturing apparatus 610 is performed before testing the semiconductor device by the testing apparatus 608. The designing apparatus 608 designs the circuit of the semiconductor device and plans and configures the semiconductor device, thereby taping out wafers for the semiconductor device. The design process of the semiconductor device is only an example, and any design process of semiconductor devices may be applied.

The manufacturing apparatus 608 manufactures products based on the design of the semiconductor device. Processes used by the manufacturing apparatus 608 can be applied to current semiconductor processes.

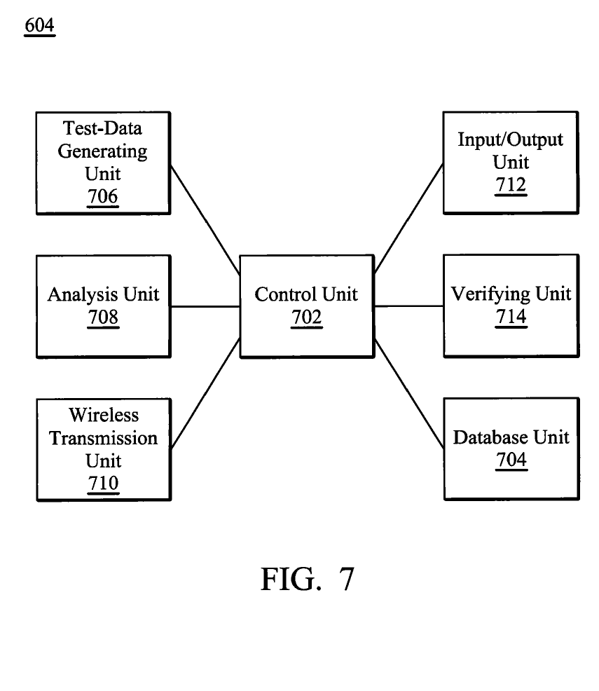

FIG. 7 is a schematic view of a test system server of the present invention.

The test system server 604 comprises a control unit 702, a database unit 704, a test-data generating unit 706, an analysis unit 708, a wireless transmitting unit 710, an input/output unit 712, and a verifying unit 714. The control unit 702 controls operations of the test system server 604. The control unit 702 comprises a microprocessor operated under software control, and logic circuits having fixed lines or combinations thereof. The database unit 704 comprises data and/or software performed by the control unit 702 and user data and authority for one or more testing apparatuses 606, control terminals 602, designing apparatuses 608, and manufacturing apparatuses 610. The test-data generating unit 706 generates test data to be tested by the testing apparatus 606 based on the type of the testing apparatus 606 and the type of the test process for the testing apparatus 606. The analysis unit 708 analyzes the test result transmitted from the testing apparatus 606. Data for analysis generated by the analysis unit 708 can be transmitted to the testing apparatus 606, the control terminal 602, the designing apparatus 608, and the manufacturing apparatus 610 via the wireless transmitting unit 710 to enhance the quality, yield rate or test performance of the semiconductor device. The wireless transmitting unit 710 wireless transmits and receives wireless information. The input/output unit 712 provides an input or output interface. The verifying unit 714 verifies a user client entering the test system server 604 or sends a test request to the user client of the test system server 604. The user client comprises the control terminal 602, the testing apparatus 606, the designing apparatus 608, and the manufacturing apparatus 610.

The following describes operations of the test system 600 for semiconductor devices based on network monitoring. The test system server 604 wirelessly receives a test request transmitted from the control terminal 602, the testing apparatus 606, the designing apparatus 608, and the manufacturing apparatus 610. The test system server 604 verifies authority of the user client sending the test request to determined whether the test request is allowed. When the test request is allowed, the test system server 604 transmits test data to the testing apparatus 606 corresponding to the test request to for a test process to a semiconductor device under test. The testing apparatus 606 wirelessly transmits a test result to the test system server 604. The test system server 604 receiving the test result analyzes the test result and wirelessly transmits the test result and information for analysis to a corresponding user client, such as the control terminal 602, the testing apparatus 606, the designing apparatus 608, and the manufacturing apparatus 610. The user at the user client modifies design or process of the semiconductor device according to the test result and the information for analysis, thereby enhancing the precision, yield rate or test quality of the semiconductor device.

An embodiment of the test system for semiconductor devices tests semiconductor devices via wireless transmission so that the number of test stations to be tested can be increased. By changing the number of transmission interfaces between the first controller and the second controllers and the number of the second controllers, the number of the dies to be tested can be increased without changing the number of the transmission channels connecting to the tester. If an input/output interface of the test station only provides 12 transmission channels (for 6 input channels and 6 output channels), the tester can only test 6 semiconductor devices. The number of semiconductor devices to be tested by the tester each time can be increased by changing the ratio of the input channels to the output channels. For example, the number of the input channels changes to 1 so the remaining 11 transmission channels can be served as the output channels. The first controller receives test information from the input channel and broadcasts the test information to multiple second controllers via infrared transmission for performing a test process. The second controllers transmit a test result to the first controller and the first controller transmits the test result to the tester via the remaining 11 transmission channel. Thus, the number of semiconductor devices to be tested by the tester each time is increased.

Further, an embodiment of the test system for semiconductor devices transmits test information via infrared transmission that transmits test information via beams without modulating transmission signals at high frequency, such that radio frequency (RF) interference or antenna effect resulting from wireless transmission may be reduced, improving and promoting test quality; especially for products to be tested which may easily generate RF interference, such as RF chips.

Additionally, the tester of the invention combines general testers and mobile terminals, which is more convenient, usable, and portable for users. Further, the tester can be used to communicate with other testing operators and transmits test information via mobile communication for enabling communication between operators on the production line.

Further, an embodiment of the test system for semiconductor devices based on network monitoring provides a real-time and convenient test environment wherein upstream and downstream departments of a manufacturer, such as the manufacturing and designing departments, can request test services and obtain real-time test results and information for analysis. The departments can decrease design and manufacturing defects to enhance yield rate and quality of products.

Methods and systems of the present disclosure, or certain aspects or portions of embodiments thereof, may take the form of a program code (i.e., instructions) embodied in media, such as floppy diskettes, CD-ROMS, hard drives, firmware, or any other machine-readable storage medium, wherein, when the program code is loaded into and executed by a machine, such as a computer, the machine becomes an apparatus for practicing embodiments of the disclosure. The methods and apparatus of the present disclosure may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for practicing and embodiment of the disclosure. When implemented on a general-purpose processor, the program code combines with the processor to provide a unique apparatus that operates analogously to specific logic circuits.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test system for semiconductor devices using network monitoring, comprising:
a testing apparatus for testing a semiconductor device through a test process;
a test system server wirelessly transmitting a test information to the testing apparatus for the test process and wirelessly receiving a test result from the testing apparatus; and
one or more control terminals wirelessly receiving the test information from the test system server to wirelessly transmit the test information to the testing apparatus for the test process,
wherein the test system server wirelessly receives a test request transmitted from a designing apparatus, a manufacturing apparatus, or the control terminals and wirelessly transmits the test result to the designing apparatus, the manufacturing apparatus or the control terminals.

2. The test system for semiconductor devices based on network monitoring as claimed in claim 1, wherein the test system server wirelessly transmits the test information to the testing apparatus for the test process for the semiconductor device according to the test request.

3. The test system for semiconductor devices based on network monitoring as claimed in claim 1, wherein the test system server analyzes the test result to obtain data for analysis.

4. The test system for semiconductor devices based on network monitoring as claimed in claim 1, wherein the test system server wireless transmits the data for analysis to the control terminals, the designing apparatus, the manufacturing apparatus or the testing apparatus.

5. The test system for semiconductor devices based on network monitoring as claimed in claim 1, wherein the control terminals wirelessly download test schedules from the test system server.

6. The test system for semiconductor devices based on network monitoring as claimed in claim 1, wherein the test system server verifies the control terminals, the designing apparatus, the manufacturing apparatus, or the testing apparatus transmitting the test request.

7. The test system for semiconductor devices based on network monitoring as claimed in claim 1, wherein the test process comprises electrical characteristic testing or wafer probe testing.

8. The test system for semiconductor devices based on network monitoring as claimed in claim 1, wherein the test system server comprises:
a control unit, controlling operations of the test system server;
a database unit, coupled to the control unit, storing data of the test system server;
a test-data generating unit, coupled to the control unit, analyzing the test results transmitted from the testing apparatus and generating the test data;
an analysis unit, coupled to the control unit, analyzing the test results transmitted from the testing apparatus and generating data for analysis;
a wireless transmitting unit, coupled to the control unit, providing wireless transmission;
an input/output unit, coupled to the control unit, providing an input or output interface; and
a verifying unit, coupled to the control unit, verifying the test request.

9. The test system for semiconductor devices based on network monitoring as claimed in claim 8, wherein data stored in the database unit comprises data or software performed by the control unit, the test data and the test result, and user data and authority for one or more of the testing apparatuses, the control terminals, the designing apparatuses, and the manufacturing apparatuses.

10. The test system for semiconductor devices based on network monitoring as claimed in claim 1, wherein the test data comprises test vectors, test commands, or combinations thereof.

11. The test system for semiconductor devices based on network monitoring as claimed in claim 1, wherein the designing apparatus designs a constitution of the semiconductor device.

12. The test system for semiconductor devices based on network monitoring as claimed in claim 1, wherein the manufacturing apparatus manufactures products of the semiconductor device.

13. The test system for semiconductor devices based on network monitoring as claimed in claim 1, wherein the control terminals comprise portable devices or mobile terminals.

14. The test system for semiconductor devices based on network monitoring as claimed in claim 1, wherein the semiconductor device comprises uncut dies or singularized dies on a wafer.

15. The test system for semiconductor devices based on network monitoring as claimed in claim 1, wherein transmission between the control terminals and the testing apparatus and transmission between the testing and the test system server is implemented by infrared transmission.

16. The test system for semiconductor devices based on network monitoring as claimed in claim 1, wherein the testing apparatus comprises:
a testing station, receiving the test information transmitted from the control terminals or the test system server via a transmission path, implementing the test process on the semiconductor device based on the test information, and transmitting the test result to the control terminals of the test system server;
a first controller, electronically coupled to the testing station, receiving the test information; and
one or more second controllers, electronically coupled to the testing station, controlling the test process of the testing station, wherein each of the second controllers corresponds to one or more of the semiconductor devices under test,
wherein the first controller broadcasts the test information to one or more of the second controllers via infrared transmission and receives the test result transmitted from the second controllers via infrared transmission.

17. A test system for semiconductor devices using network monitoring, comprising:
a testing apparatus for testing a semiconductor device through a test process; and
a test system server wirelessly transmitting a test information to the testing apparatus for the test process and wirelessly receiving a test result from the testing apparatus,
wherein the test system server wirelessly receives a test request transmitted from a designing apparatus, a manufacturing apparatus, or the testing apparatus and wirelessly transmits the test result to the designing apparatus or the manufacturing apparatus.
